(19) United States
(12) Patent Application Publication
(10) Pub. No.: US 2019/0280354 A1
(43) Pub. Date: Sep. 12, 2019

(54) BLAST TUBING FOR PACKAGING BATTERY CELLS

(71) Applicant: INTERNATIONAL BUSINESS MACHINES CORPORATION, ARMONK, NY (US)

(72) Inventors: Robert B. Schlak, Hyde Park, NY (US); Noah Singer, New City, NY (US); John Torok, Poughkeepsie, NY (US); Xiaojin Wei, Poughkeepsie, NY (US); Mitchell Zapotoski, New Paltz, NY (US)

(21) Appl. No.: 15/912,601

(22) Filed: Mar. 6, 2018

(51) Int. Cl. H01M 10/6555; H01M 10/42; H01M 10/6551; H05K 1/02; H01M 2/06; H01M 10/613

(52) U.S. Cl. CPC H01M 10/6555; H01M 10/4257; H01M 10/6551; H01M 10/0525; H01M 2/06; H01M 10/613; H05K 1/0212

(57) ABSTRACT

An apparatus for containing battery cells includes a containment structure disposed on a printed circuit board for encasing a first battery cell, the first battery cell being electrically coupled to the printed circuit board, the containment structure being a first blast plate structure coupled a first blast tube structure. The apparatus further includes the first blast tube structure partially surrounding the first battery cell, where a bottom surface of a first end of the first blast tube structure is coupled to a top portion of the printed circuit board. The apparatus further includes the first blast plate structure coupled to a top surface of a second end of the first blast tube structure. The apparatus further includes a first thermal interface material at least partially surrounding the first battery cell, where the first thermal interface material is located between the first battery cell and the first blast tube structure.

### FIELD OF THE INVENTION

This disclosure relates generally to packaging battery cells, and in particular, to structures for containing individual packaged battery cells.

### BACKGROUND OF THE INVENTION

Over time, energy density in batteries has increased, while packaging size for the batteries has decreased. Lithium ion batteries are an example of high energy density batteries and have become the preferred battery technology for items such as, consumer electronics, electric vehicles, battery backup systems, and other energetic systems requiring a mobile and rechargeable power source. A byproduct of high energy density is that lithium ion batteries pose a greater safety risk than lower energy density technologies, due to the amount of chemical energy stored in a small package. A mechanism by which high energy density batteries fail energetically is called thermal runaway, a condition where the chemical reaction inside a single cell becomes unstable due to excessive heat which may be generated by an internal defect or by other means. Thermal runaway causes the single cell to continue to heat up at an ever-accelerating rate until the structural integrity of the single cell is compromised or the single cell combusts.

### SUMMARY

One aspect of an embodiment of the present invention discloses an apparatus for containing packaged battery cells, the apparatus comprising a containment structure disposed on a printed circuit board for encasing a first battery cell, the first battery cell being electrically coupled to the printed circuit board, the containment structure being a first blast plate structure coupled a first blast tube structure. The apparatus includes the first blast tube structure partially surrounding the first battery cell, wherein a bottom surface of a first end of the first blast tube structure is coupled to a top portion of the printed circuit board. The apparatus further includes the first blast plate structure coupled to a top surface of a second end of the first blast tube structure. The apparatus further includes a first thermal interface material at least partially surrounding the first battery cell, wherein the first thermal interface material is located between the first battery cell and the first blast tube structure.

### BRIEF DESCRIPTION OF THE SEVERAL VIEWS OF THE DRAWINGS

The following detailed description, given by way of example and not intended to limit the disclosure solely thereto, will best be appreciated in conjunction with the accompanying drawings, in which:

FIG. 1 depicts a battery cell board assembly with a blast plate and blast tubing for each battery cell, in accordance with an embodiment of the present invention.

FIG. 2 depicts a battery cell board assembly with blast tubing and exposed insulation caps for each battery cell, in accordance with an embodiment of the present invention.

FIG. 3 depicts an individual battery cell encased in blast tubing, in accordance with one embodiment of the present invention.

FIG. 4 depicts an individual battery cell from FIG. 3 with removed blast tubing, in accordance with one embodiment of the present invention.

FIG. 5 depicts an individual battery cell from FIGS. 3 and 4 with removed blast tubing and thermal interface material, in accordance with one embodiment of the present invention.

FIG. 6 depicts a bottom view of an individual battery cell encased in blast tubing, in accordance with one embodiment of the present invention.

FIG. 7 depicts a top view of an individual battery cell encased in blast tubing with an insulation cap removed, in accordance with one embodiment of the present invention.

FIG. 8 depicts a top view of a portion of battery cell board assembly, in accordance with one embodiment of the present invention.

FIG. 9 depicts a top view of a portion of battery cell board assembly, in accordance with one embodiment of the present invention.

FIG. 10 depicts a top view of a portion of battery cell board assembly, in accordance with one embodiment of the present invention.

### DETAILED DESCRIPTION

Larger battery cell packages containing multiple battery cells are typically cooled utilizing liquid coolant, where the coolant flows through tubing and piping around the battery cells to cool the battery cell package. The coolant draws heat away from the battery cells and allows for a containment unit to be placed around the cells to prevent a thermal runaway event from escaping the confines of the battery cell package. Some larger battery cell packages separate the battery cells into smaller clusters or modules which are isolated, preventing a cascading failure of all the battery cells in the battery cell package. It is atypical to provide cooling to larger battery cell packages utilizing air flow due to the difficulty of containing battery cells. The containment of battery cells prevents an uncontrolled event (e.g., fire) from exiting the battery cell package and causing damage or injury. The containment of a single battery cell prevents a single battery cell thermal runaway event from propagating to surrounding battery cells and creating a thermal runaway event across all the battery cells within the battery cell package.

Embodiments of the present invention provide an apparatus for cooling and containing battery cells in a battery cell package, while utilizing accelerated airflow as a primary cooling method. Each battery cell includes an individual blast tube structure, where the blast tube structure is made of a thermally conductive and mechanically durable material (e.g., aluminum and/or ceramic). The blast tube structure encases a single battery cell to contain a possible thermal event (e.g., fire and/or combustion) to the single battery cell, preventing the thermal event from propagating to surrounding battery cells within the battery cell package. Each blast tube structure is coupled at one end to a printed circuit board forming an array of blast tube structures, allowing for the battery cells encase in each blast tube structure to be electrically coupled to one another and to the rest of the battery package system.

A blast plate structure is coupled to the array of blast tube structures to contain a thermal event in the positive y-axis direction. A secondary blast plate structure can be coupled to a bottom surface of the printed circuit board, where a void is present between the bottom surface of the printed circuit board and the secondary blast plate structure. The void allows for the placement of electrical components on the bottom surface of the printed circuit board and the void allows for pressure relief for the battery cells through apertures in the printed circuit board. Each blast tube structure has a dedicated aperture in the printed circuit board to allow for gas to flow out through the battery cell during a high-pressure event, through the aperture in the printed circuit board, and out into the void between the printed circuit board and the secondary blast plate.

A method for manufacturing a battery cell with a blast tube structure includes electrically coupling two leads to the battery cell. A shorter lead is electrically coupled to a bottom surface of an end of the battery cell and electrically coupled to the printed circuit board. A longer lead is electrically coupled to a top surface of another end of the battery cell, where the longer lead spans the length of the battery cell and electrically couples to the printed circuit board. Electrically insulating shrink tubing is wrapped around the battery cell to cover the longer lead spanning the length of the battery cell. Subsequently, the battery cell is wrapped or coated in thermal interface material to enhance thermal coupling between the electrically insulating shrink tubing and the blast tube structure. The blast tube structure is placed around the battery cell and secured utilizing seam welding or other securing methods known in the art. The battery cell with the blast tube structure is secured to the printed circuit board utilizing a heat resistance adhesive along a lower surface of the blast tube structure that couples to a top surface of the printed circuit board. A blast plate structure is secured to the blast tube structure utilizing the heat resistance adhesive along an upper surface of the blast tube structure that is coupled to a lower surface of the blast plate structure.

As one or more fans accelerate air towards the array of blast tube structures, the accelerated air contacts the exterior surface of each blast tube structure and cools the blast tube structure with the battery cell encased within. Since the battery cell is thermally coupled to the blast tube structure via the thermal interface material, heat can transfer from the battery cell to the exterior surface of the blast tube structure. The array of blast tubes with encased battery cells are simultaneously contained and cooled utilizing the accelerated air cooling method.

Detailed embodiments of the present invention are disclosed herein with reference to the accompanying drawings; however, it is to be understood that the disclosed embodiments are merely illustrative of potential embodiments of the invention and may take various forms. In addition, each of the examples given in connection with the various embodiments is also intended to be illustrative, and not restrictive. This description is intended to be interpreted merely as a representative basis for teaching one skilled in the art to variously employ the various aspects of the present disclosure. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements. The term substantially, or substantially similar, refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Many common fabrication techniques involve securing two objects using an adhesive layer between the objects. Often times the adhesive layer is chosen in an attempt to permanently secure the two objects together. And while this adhesive layer selection may be advantageous for typical usage of the overall product, there may be instances where separation of the joined objects is either desired, or necessary. In such instances, separation of the two objects, without physically damaging either of the objects, may be required so that one or both of the objects may be reused.

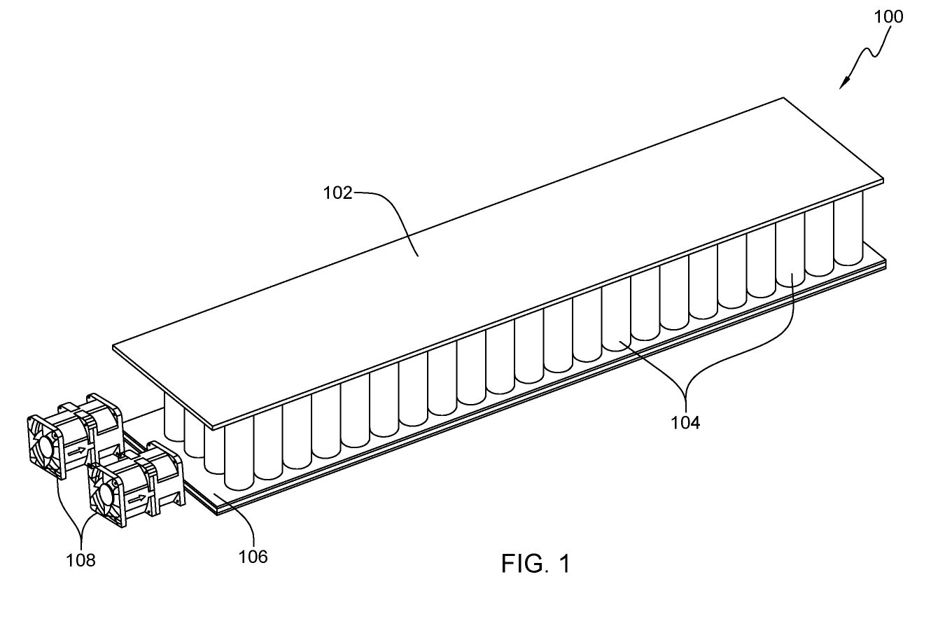

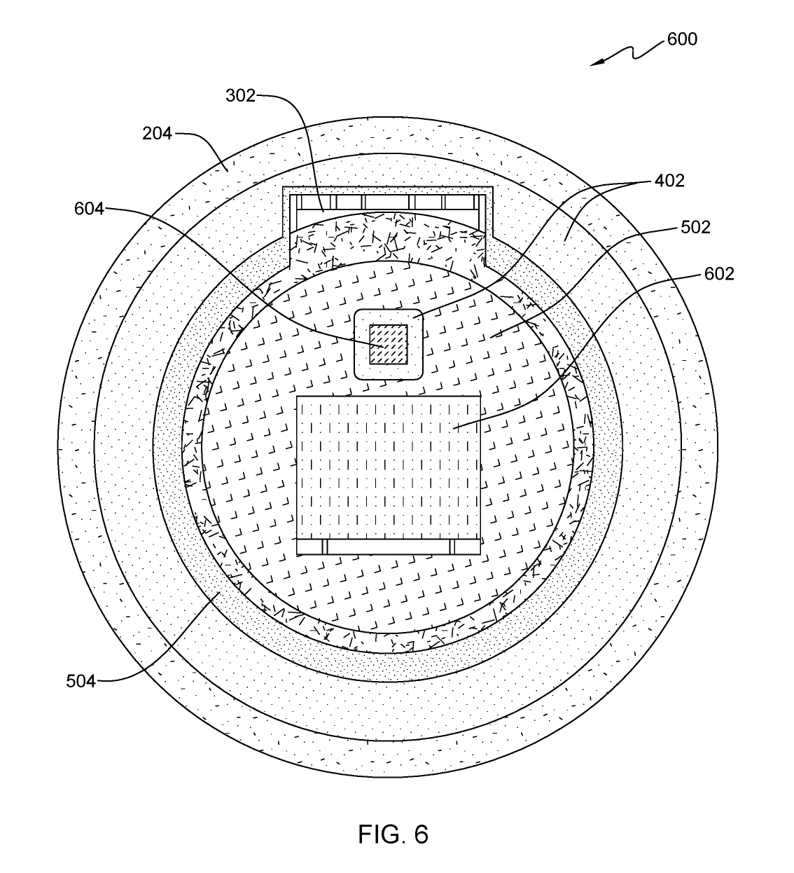

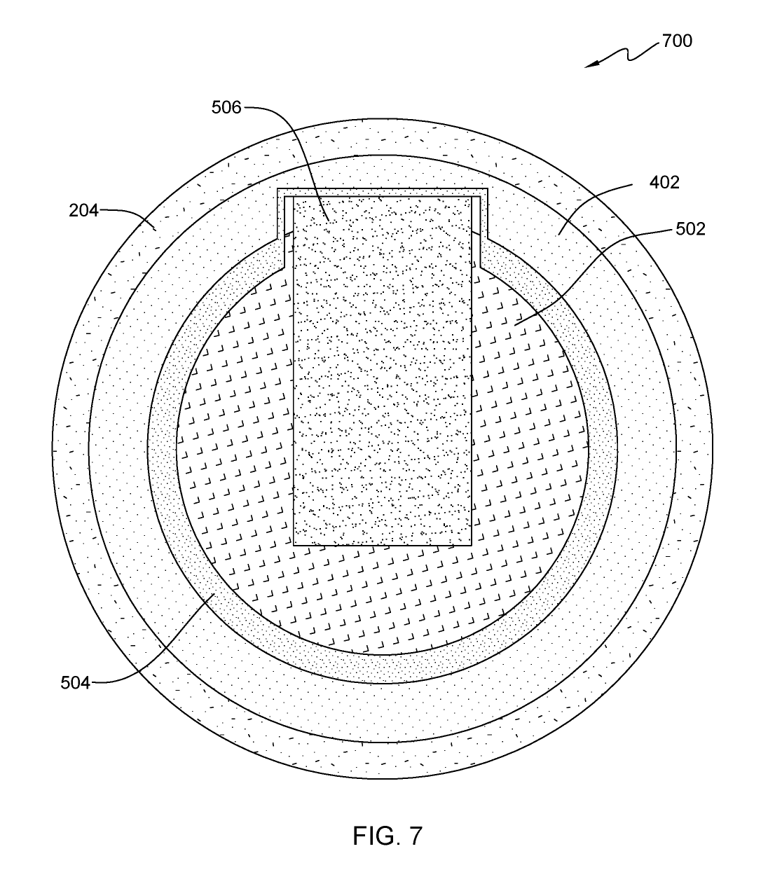

FIG. 1 depicts a battery cell board assembly with a blast plate and blast tubing for each battery cell, in accordance with an embodiment of the present invention. In this embodiment, battery cell board assembly 100 includes blast plate 102, battery cell tubes 104, and printed circuit board (PCB) 106. Battery cell board assembly 100 includes an array of battery cell tubes 104 spanning the length of PCB 106. Each battery cell tube 104 encases a battery cell and various battery cell components, discussed in further detail in FIGS. 6 and 7. A bottom surface of a first end of each battery cell tube 104 is coupled to a top surface of PCB 106 and a top surface of a second end of each battery cell tube 104 is coupled to a bottom surface of blast plate 102. Blast plate 102 and battery cell tubes 104 can be made of thermally conductive material such as, different types of aluminum and ceramics. Each battery cell tube 104 can couple to blast plate 102 and PCB 106 utilizing a heat resistant adhesive, where each battery cell tube 104 is sealed on both ends by blast plate 102 and PCB 106. Sealing each battery cell tube 104 prevents a thermal event occurring in a single battery cell tube 104, from propagating to surrounding battery cell tubes 104 (i.e., thermal runaway). In an alternative embodiment, blast plate 102 and battery cell tubes 104 are a single mountable structure coupled to PCB 106, where the singled mountable structure is placed over the multiple battery cells and battery cell components encased by battery cell tubes 104.

In another embodiment, a secondary blast plate is coupled to a bottom surface of the PCB 106, where a void is present between the bottom surface of PCB 106 and the secondary blast plate structure. The void allows for the placement of electrical components on the bottom surface of PCB 106 and the void allows for pressure relief for the battery cells through one or more apertures in PCB 106. Each battery cell tube 104 includes one or more dedicated apertures in PCB 106 to allow for gas to flow out through the battery cell during a high-pressure event, through the one or more apertures in PCB 106, and out into the void between PCB 106 and the secondary blast plate. In yet another embodiment, each battery cell tube 104 includes one or more dedicated apertures in blast plate 102 to allow for gas to flow out through the battery cell during a high-pressure event, through the one or more apertures in blast plate 102, and away from the surrounding battery cell tubes 104.

For illustration purposes, FIG. 1 does not include an enclosure for battery cell board assembly 100, where the enclosure encompasses battery cell board assembly 100. Cooling fans 108 located at a first end (front portion) of battery cell board assembly 100 accelerates air towards battery cell tubes 104 and exhausts air away from battery cell tubes 104 at a second end (rear portion) of battery cell board assembly 100. The enclosure at the first end of battery cell board assembly 100 includes inlet apertures for air intake and the enclosure at the second end of battery cell board assembly 100 includes outlet apertures for exhausting air away from battery cell board assembly 100.

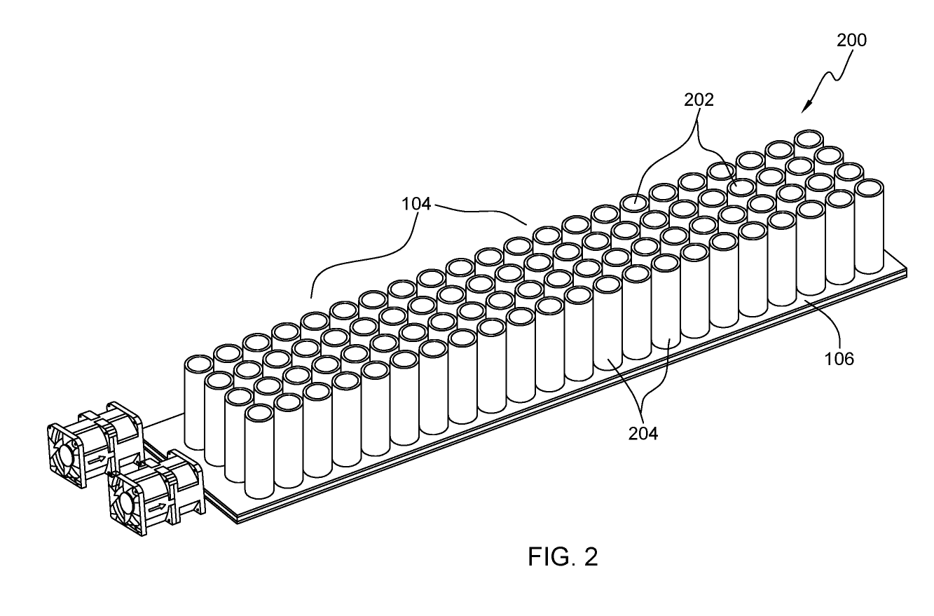

FIG. 2 depicts a battery cell board assembly with blast tubing and exposed insulation caps for each battery cell, in accordance with an embodiment of the present invention. In this embodiment, blast plate 102 from FIG. 1 is removed from partial battery cell board assembly 200, exposing a top potion of each battery cell tube 104. As previously discussed, multiple rows of battery cell tubes 104 span the length of PCB 106, where each battery cell tube 104 is isolated, with voids present in between the battery cell tubes 104. Each battery cell tube 104 includes insulation cap 202 and blast tube 204. Insulation cap 202 provides a medium between a top surface of a battery cell in blast tube 204 and blast plate 102 (illustrated in FIG. 1). Alternatively, insulation cap 202 is optional for each battery cell tube 104 if blast plate 102 and blast tube 204 are made of non-electrically conducting materials.

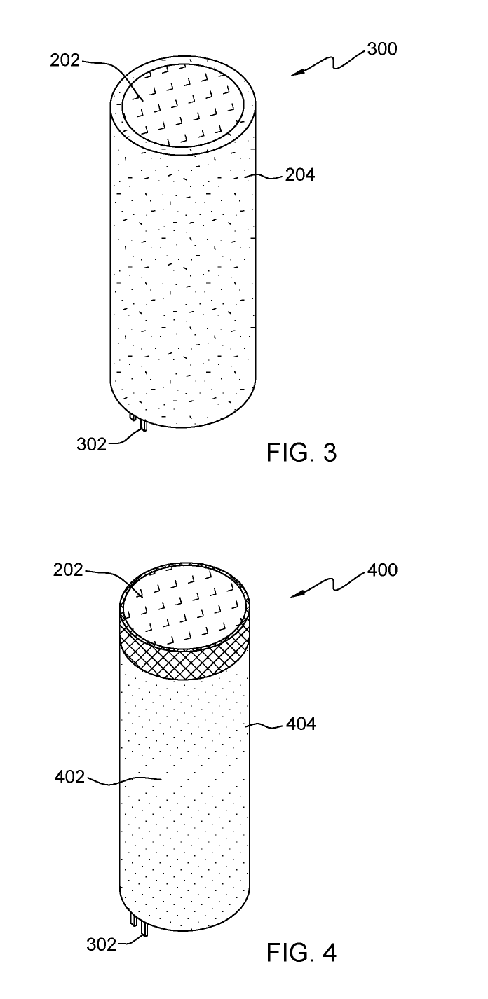

FIG. 3 depicts an individual battery cell encased in blast tubing, in accordance with one embodiment of the present invention. In this embodiment, individual battery cell tube 300 includes insulation cap 202 and blast tube 204, where blast tube 204 is a single piece of thermally conductive material. In an alternative embodiment, blast tube 204 includes two pieces of thermally conductive material, where the two pieces of thermally conductive material are coupled lengthwise along individual battery cell tube 200. Alternatively, the two pieces of thermally conductive material can be coupled along a circumference of individual battery cell tube 200, where a top portion of thermally conductive material is coupled to a bottom portion of thermally conductive material. Battery cell lead 302 extends beyond a lower surrounding edge of blast tube 204, such that battery cell lead 302 electrically couples to PCB 106 (not illustrated in FIG. 3) and the lower surrounding edge of blast tube 204 creates a seal between individual battery cell tube 300 and PCB 106. Additionally, a heat resistant adhesive can be applied on the circumference of the lower surrounding edge of blast tube 204 to create the seal with PCB 106.

In this embodiment, insulation cap 202 is situated below an upper surrounding edge of blast tube 204, leaving a medium for insulation cap 202 to expand during various heat cycles. Alternatively, insulation cap 202 can extended above an upper surrounding edge of blast tube 204, where coupling blast plate 102 to the upper surrounding edge of blast tube 204 compresses insulation cap 202. The upper surrounding edge of blast tube 204 creates a seal between individual battery cell tube 300 and blast plate 102, where a heat resistant adhesive can be applied on the circumference of the upper surrounding edge of blast tube 205 to create the seal with blast plate 102.

FIG. 4 depicts an individual battery cell from FIG. 3 with removed blast tubing, in accordance with one embodiment of the present invention. In this embodiment, individual battery cell 400 illustrates individual battery cell tube 300 with removed blast tube 204, exposing first portion thermal interface material 402 and second portion thermal interface material 404. First portion thermal interface material 402 and second portion thermal interface material 404 provide a thermal path for heat to flow from the battery cell to blast tube 204.

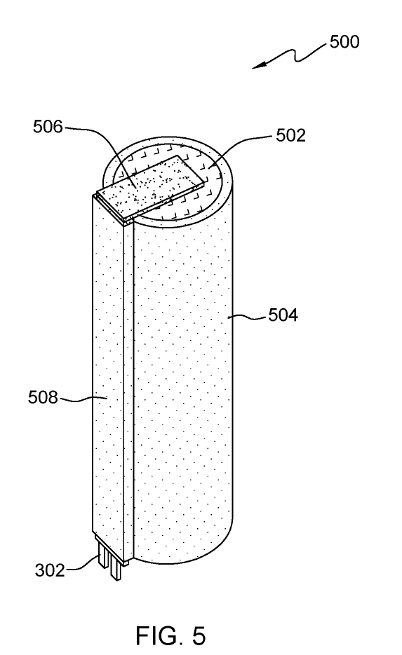

FIG. 5 depicts an individual battery cell from FIGS. 3 and 4 with removed blast tubing and thermal interface material, in accordance with one embodiment of the present invention. In this embodiment, battery cell 500 illustrates individual battery cell 400 with removed insulation cap 202, first portion thermal interface material 402, and second portion thermal interface material 404. Assembly of battery cell 500 includes coupling top surface lead 506 to cell 502, where top surface lead 506 electrically couples to PCB 106 via connecting lead 508 and battery cell lead 302. Assembly of battery cell 500 also includes coupling a bottom surface lead to cell 502, not illustrated in FIG. 5. The coupling of top surface lead 506 to cell 502 and the bottom surface lead to cell 502 can including spot-welding top surface lead 506 to a top surface of cell 502 and spot-welding the bottom surface lead to a bottom surface of cell 502. Subsequently, shrink tubing 504 is applied around cell 502 and connecting lead 508, where shrink tubing 504 provides electrical insulation between connecting lead 508 and blast tube 204. However, if blast tube 204 is made of non-electrically conducting materials (e.g., ceramics), shrink tubing 504 is not required for battery cell 500.

FIG. 6 depicts a bottom view of an individual battery cell encased in blast tubing, in accordance with one embodiment of the present invention. In his embodiment, bottom portion 600 of individual battery cell tube 300 resides on a top surface of PCB 106, where battery cell lead 302 provides a first electrical connection and bottom surface lead 602 provides a second electrical connection between cell 502 and PCB 106. Shrink tubing 504 partially encases cell 502, first portion thermal interface material 402 and second portion thermal interface material 404 partially encases shrink tubing 504, and blast tube 204 partially encases first portion thermal interface material 402 and second portion thermal interface material 404. Thermal sensor 604 (e.g., thermistor) is coupled to cell 502, where a third portion of thermal interface material can be utilized between cell 502 and thermal sensor 604 to prevent electrical conduction and to enhance thermal conduction.

Alternatively, thermal sensor 604 can be coupled to the top surface of PCB 106 under bottom portion 600 of individual battery cell tube 300. Thermal sensor 604 monitors thermal variations of cell 502.

FIG. 7 depicts a top view of an individual battery cell encased in blast tubing with an insulation cap removed, in accordance with one embodiment of the present invention. In his embodiment, top portion 600 of individual battery cell tube 300 is illustrated with insulation cap 202 removed. Shrink tubing 504 partially encases cell 502, first portion thermal interface material 402 and second portion thermal interface material 404 partially encases shrink tubing 504, and blast tube 204 partially encases first portion thermal interface material 402 and second portion thermal interface material 404. Top surface lead 506 electrically couples to PCB 106 via connecting lead 508 and battery cell lead 302, where shrink tubing 504 covers connecting lead 508 situated along the length of cell 502.

FIG. 8 depicts a top view of a portion of battery cell board assembly, in accordance with one embodiment of the present invention. In this embodiment, battery cell tubes 104 are oriented on PCB 106 in parallel and each battery cell tube 104 is equally spaced relative to another battery cell tube 104. Distance 802 measured from a center of a first battery cell tube 104 to a center of a second battery cell is equal to distance 804 measured from a center of a third battery cell to the center of the second battery cell and distance 802 is perpendicular to distance 804.

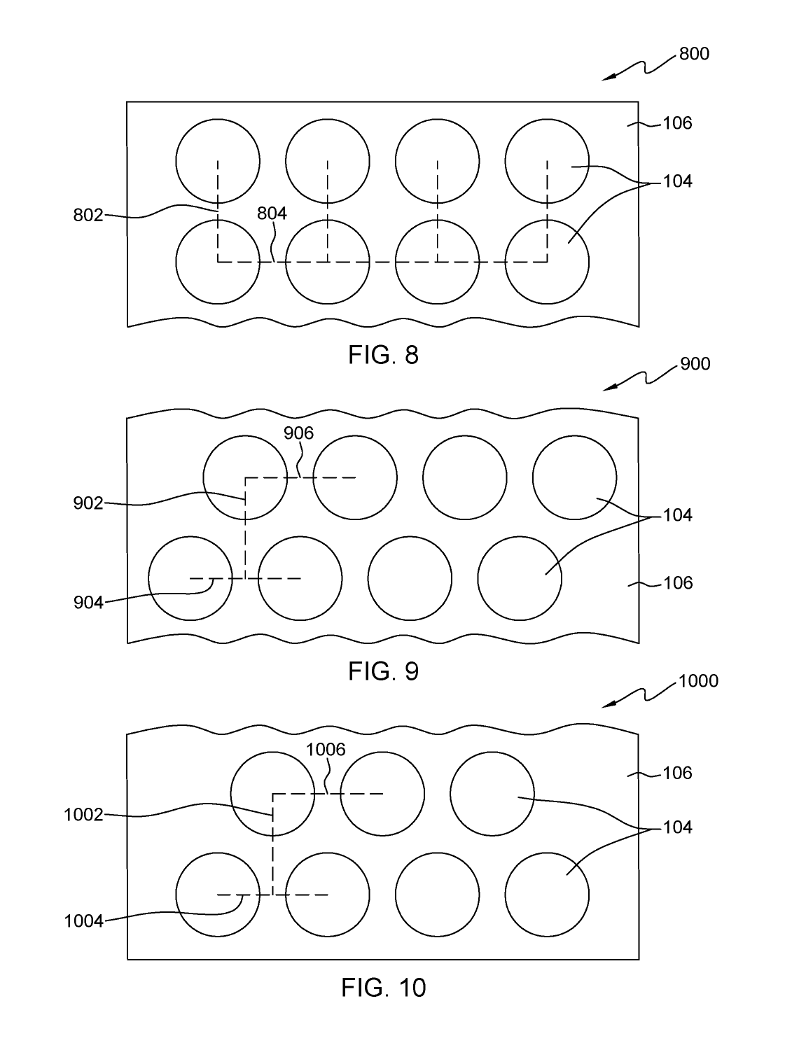

FIG. 9 depicts a top view of a portion of battery cell board assembly, in accordance with one embodiment of the present invention. In this embodiment, battery cell tubes 104 are oriented to maximize surface area of PCB 106, where a first row of battery cell tubes 104 is offset relative to a second row of battery cell tubes 104. Distance 902 measured from a center of a first battery cell tube 104 to a center of distance 904, is equal to distance 906 measured from a center of a second battery cell tube 104 to the first battery cell tube 104, where distance 904 is measured from a center of third battery cell tube 104 and a center of a fourth battery cell tube 104. Voids between exterior walls of each battery cell tube 104 are minimized in this example orientation to improve battery cell tube 104 packaging on PCB 106.

FIG. 10 depicts a top view of a portion of battery cell board assembly, in accordance with one embodiment of the present invention. In this embodiment, battery cell tubes 104 are oriented on PCB 106 to maximize heat dissipation, where a first row of battery cell tubes 104 is offset relative to a second row of battery cell tubes 104 with a varying amount of battery cell tubes 104 across the two rows. Distance 1002 measured from a center of a first battery cell tube 104 to a center of distance 1004, is equal to distance 1006 measured from a center of a second battery cell tube 104 to the first battery cell tube 104, where distance 1004 is measured from a center of third battery cell tube 104 and a center of a fourth battery cell tube 104. Voids between exterior walls of each battery cell tube 104 are increased in this example orientation to allow for increased heat dissipation.

The terminology used herein is for the purpose of describing particular embodiments only and is not intended to be limiting to the invention. As used herein, the singular forms “a”, “an” and “the” are intended to include the plural forms as well, unless the context clearly indicates otherwise.

Having described preferred embodiments of a cooled containment compartment for package battery cells (which are intended to be illustrative and not limiting), it is noted that modifications and variations may be made by persons skilled in the art in light of the above teachings. It is therefore to be understood that changes may be made in the particular embodiments disclosed which are within the scope of the invention as outlined by the appended claims.

What is claimed is:

1. An apparatus for containing packaged battery cells, the apparatus comprising:
a containment structure disposed on a printed circuit board for encasing a first battery cell, the first battery cell being electrically coupled to the printed circuit board, the containment structure being a first blast plate structure coupled a first blast tube structure;
the first blast tube structure partially surrounding the first battery cell, wherein a bottom surface of a first end of the first blast tube structure is coupled to a top portion of the printed circuit board;
the first blast plate structure coupled to a top surface of a second end of the first blast tube structure; and
a first thermal interface material at least partially surrounding the first battery cell, wherein the first thermal interface material is located between the first battery cell and the first blast tube structure.

2. The apparatus of claim 1, further comprising:
a first insulation cap resting on a top surface of a second end of the first battery cell, wherein the first insulation cap is positioned between the first blast plate structure and the top surface of the second end of the first battery cell, and wherein the first blast tube structure at least partially surrounding the first insulation cap.

3. The apparatus of claim 1, further comprising:
a first aperture of the printed circuit board located within an area of the first end of the first blast tube structure.

4. The apparatus of claim 1, further comprising:
a first aperture of the first blast plate structure located within an area of the second end of the first blast tube structure.

5. The apparatus of claim 1, wherein the first blast tube structure comprises a ceramic material.

6. The apparatus of claim 1, wherein the first blast plate structure comprises a ceramic material.

7. The apparatus of claim 1, further comprising:
a thermal sensor coupled to the bottom surface of a first end of the first battery cell, wherein a second thermal interface material is located between the first end of the first battery cell a first surface of the thermal sensor.

8. The apparatus of claim 1, further comprising.
a heat resistant adhesive located between the first blast plate structure coupled to the top surface of the second end of the first blast tube structure.

9. The apparatus of claim 1, further comprising:
a heat resistant adhesive located between the first blast plate structure coupled to the top surface of the second end of the first blast tube structure.

10. The apparatus of claim 1, wherein the first battery cell and the first blast tube structure are cylindrical in shape.

11. The apparatus of claim 10, wherein the first blast tube structure at least partially surrounding the first battery cell around a central axis of the first battery cell.

12. The apparatus of claim 1, further comprising:
a second battery cell, wherein a bottom surface of a first end of the second battery cell is electrically coupled to the top portion of the printed circuit board;
a second blast tube structure at least partially surrounding the second battery cell, wherein a bottom surface of a first end of the second blast tube structure is coupled to the top portion of the printed circuit board; and
the first blast plate structure coupled to a top surface of a second end of the second blast tube structure, wherein the first blast plate structure, the second blast tube structure, and the top portion of the printed circuit board encase the second battery cell.

13. The apparatus of claim 1, further comprising:
a second battery cell, wherein a bottom surface of a first end of the second battery cell is electrically coupled to the top portion of the printed circuit board;
a second blast tube structure at least partially surrounding the second battery cell, wherein a bottom surface of a first end of the second blast tube structure is coupled to the top portion of the printed circuit board; and
a second blast plate structure coupled to a top surface of a second end of the second blast tube structure, wherein the second blast plate structure, the second blast tube structure, and the top portion of the printed circuit board encase the second battery cell.

14. The apparatus of claim 12, wherein a void exists between the first blast tube structure and the second blast tube structure.

15. The apparatus of claim 13, wherein a void exists between the first blast tube structure and the second blast tube structure.

16. An apparatus for containing packaged battery cells, the apparatus comprising:
a plurality of battery cells, wherein a bottom surface of a first end of each of the plurality of battery cells is electrically coupled to a top portion of a printed circuit board;
a plurality of blast tube structures at least partially surround the plurality of the first battery cell, wherein a bottom surface of a first end of each of the plurality of blast tube structures is coupled to the top portion of the printed circuit board; and
a blast plate structure located on a top surface of a second end of each of the plurality of blast tube structures, wherein the blast plate structure, the plurality of blast tube structures, and the top portion of the printed circuit board encase the plurality of battery cells.

17. The apparatus of claim 16, wherein the plurality of blast structures and the blast plate structure form a single mountable structure.

18. The apparatus of claim 16, further comprising:
a plurality of insulation caps resting on a top surface of a second end of each of the plurality of the battery cells, wherein each of the plurality of insulation caps is positioned between the blast plate structure and the top surface of the second end of each of the plurality of battery cells.

19. The apparatus of claim 16, wherein a plurality of voids exist between each of the plurality of blast tube structures.

20. The apparatus of claim 16, further comprising.
a heat resistant adhesive located between the blast plate structure coupled to the top surface of the second end of each of the plurality of blast tube structures.
